(19) United States
(12) Patent Application Publication
(10) Pub. No.: US 2013/0328067 A1
(43) Pub. Date: Dec. 12, 2013

(54) LED MODULE

(71) Applicant: FENG CHIA UNIVERSITY, Seatwen Taichung (TW)

(72) Inventors: Ching-fu TSOU, Seatwen Taichung (TW); Cheng-Han Huang, Seatwen Taichung (TW); Kuo-Chun Tseng, Seatwen Taichung (TW); Sheng-Wei Chang, Seatwen Taichung (TW)

(73) Assignee: Feng Chia University, Seatwen Taichung (TW)

(21) Appl. No.: 13/623,499

(22) Filed: Sep. 20, 2012

(30) Foreign Application Priority Data
Jun. 8, 2012 (TW) 101120593

(51) Int. Cl. H01L 31/12

(52) U.S. Cl. 257/84; 257/E31.096

(57) ABSTRACT

An LED module includes a silicone substrate, an LED grain mounted on a face of the silicone substrate, a temperature sensor formed under the LED grain, a luminous sensor formed close to the LED grain and an encapsulation gel enclosing the LED grain, wherein the LED grain, the luminous sensor and the temperature sensor are electrically connected to electrodes for connection to foreign devices.

### CROSS-REFERENCE TO RELATED APPLICATION

This application claims priority from application No. 101120593, filed on Jun. 8, 2012 in the Taiwan Intellectual Property Office.

### FIELD OF THE INVENTION

The invention relates to a light emitting diode (LED), and more particularly, to a LED with a temperature sensor and a photo sensor.

### BACKGROUND OF THE INVENTION

Light emitting diode (LED) has high illumination efficiency, long life span and low power consumption characteristics and has been gradually used to replace the conventional high energy-consumption and environment-contaminant fluorescence lights which are used both indoors and outdoors by the promotion of the government agencies. Its function is thus extended from pure lighting to different applications, such as the potential visible light communication. The luminous effect has been increased due to a lot of adds-on values. Also, the brightness requirement is up grated following the trend.

In the development and function diversified route of LED, challenges follow suits. For example, when LED with high power is used in high luminous requirement environment, high temperature is easily expected and thus luminance is decreased and color temperature changes, which affects the reliability and life span of the LED. In order to maintain normal function of the LED, large scale heat dissipating device or element is required. The photoelectric effect of the crystalline grain is decreased following lapse of time and under extreme environment, which leads to deterioration of the luminance and color temperature change under the same current. Therefore, it is required to control the luminance quality of LED via temperature sensing and signal feedback.

There have been arts researching the control of luminance and temperature via exterior sensors to sense luminance and temperature as well as signal feedback. However, the overall system is bulky, expensive and complicated and not able to satisfy monitor in real-time.

Studies also show that even installing a temperature sensor inside LED to constantly monitor temperature change while LED is in application, the temperature sensor is not manufactured with the LED, it is added to the LED after LED is made, which increases barriers to mass production of LED.

### SUMMARY OF THE INVENTION

In one aspect of the present invention, a novel LED module is provided with a luminous sensor and a temperature sensor during the manufacture process of the LED.

In order to accomplish the aforementioned objective, the LED module of the preferred embodiment of the present invention has at least one LED grain on a silicone substrate with a temperature sensor and a luminous sensor embedded inside the substrate. The temperature sensor in positioned at the bottom of the at least one LED grain, and the luminous sensor is located close to the at least one LED grain. The at least one LED grain encapsulated in an encapsulation gel, the temperature sensor and the luminous sensor are all electrically connected to electrodes which are then electrically connected to foreign devices.

### BRIEF DESCRIPTION OF THE DRAWINGS

FIG. 1 is a schematic cross-sectional view of a preferred embodiment of the LED module of the present invention;

FIG. 2 is a top plan view of a portion of FIG. 1;

FIG. 3 is a schematic cross sectional view of a preferred embodiment of the present invention;

FIG. 4 is a schematic cross sectional view of a preferred embodiment of the present invention; and

FIG. 5 is still another schematic cross sectional view of a preferred embodiment of the present invention.

### DETAILED DESCRIPTION OF THE INVENTION

Other features and advantages of the invention will become apparent after the following detailed description of a preferred embodiment with reference to the accompanying drawings.

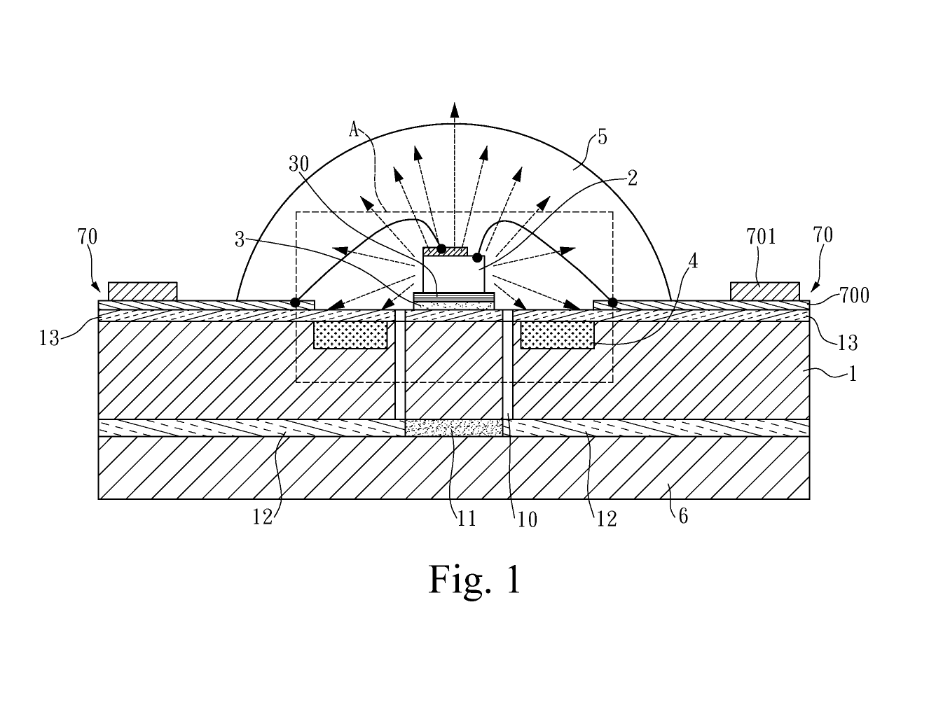

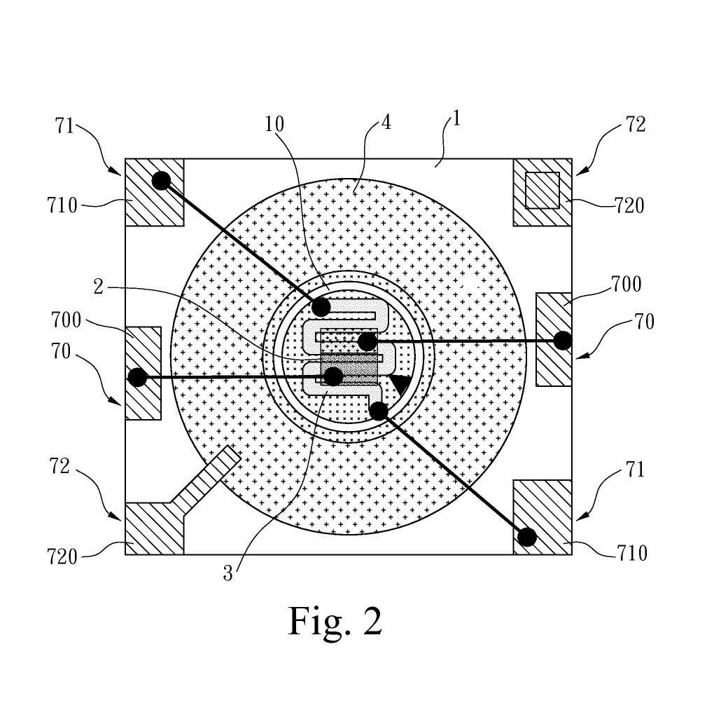

With reference to FIGS. 1 and 2, an embodiment of a LED module according to one embodiment of the invention is presented. The LED module includes a silicone substrate 1, a LED grain 2 on top of the substrate 1, a temperature sensor 3 positioned at bottom of the LED grain 2 and a luminous sensor 4 located close to the LED grain 2.

The LED grain 2, the temperature sensor 3 and the luminous sensor 4 are all encapsulated in an encapsulation gel 5 of epoxy resin to prevent the LED grain 2, the temperature sensor 3 and the luminous sensor 4 from contact with air. The LED grain 2, the temperature sensor 3 and the luminous sensor 4 are also electrically connected to electrodes for connection with foreign devices.

In this embodiment of the present invention, the substrate 1 is a N-type silicone substrate and the luminous sensor 4 is a P-type doped area with electric holes. The luminous sensor 4 is made via lithography and doping. By way of the P-N junction of semiconductor characteristic, the light from the LED grain or light reflected by other elements in on the light sensor 4, the migration of electric holes causes the transformation of photo-energy to electromotive force. It is also known that the luminosity intensity is proportional to the output of electromotive force. Therefore, it is known from the output electromotive force the luminosity intensity of the LED grain 2.

The temperature sensor 3 is a resistive metallic membrane and formed on the substrate 1 via membrane deposition as well as lithography. An adhesive gel 30 is applied on top of the temperature sensor 3 so that the LED grain 2 is securely mounted on top of the temperature sensor 3.

An annular trough 10 is defined surrounding the LED grain 2 so as to isolate the luminous sensor 4 from the LED grain 2. The purpose of having this annular trough 10 is to prevent the heat generated by the LED grain 2 from conducting to juncture between the N-type silicone substrate 1 and the P-type luminous sensor 4 so as to affect the accuracy of luminosity measurement. A heat conducting plate 6 is provided at the bottom of the silicone substrate 1. In this embodiment of the present invention, the heat conducting plate 6 is made of silicone; however, the heat conducting plate 6 may also be made of metal or ceramic in other embodiments. At the juncture of the bottom of the annular trough 10 and the top of the heat conducting plate 6, a heat conducting gel 11 is provided to fast and effectively direct the heat from the LED grain 2 to the ambient so as to maintain working temperature to all related elements. As silicone has great heat conducting coefficient (1.57 w/cm), with the assistance of the N-type substrate 1, the heat conducting gel 11 and the heat conducting plate 6, heat so generated is fast dissipated to the ambient. Again, because the mechanical features of the silicone substrate 1 are close to those of the LED grain 2, influence from heat stress is reduced and thus reliability and life span of the product are enhanced. As for poly-grain or even more powerful light sources, additional heat conducting devices or compulsory heat convection devices are required to lower the temperature.

As shown in FIG. 1, a heat insulation layer 12 is sandwiched between the silicone substrate 1 and the heat conducting plate 6 to avoid fast heat conduction from the heat conducting plate 6 to the P-N juncture of the silicone substrate 1 and the luminous sensor 4. An insulation layer 13 formed by deposition is located on the top of the silicone substrate 1 and on the face surrounded by the annular trough 10. When the LED grain 2 is in application and heat so generated will be quickly conducted via the adhesive gel 30 to temperature sensor 3. Because the resistance of the metallic membrane of the temperature sensor 3 changes in response to changes of temperature, from the temperature difference between two ends of the metallic membrane of the temperature sensor 3, it is able to correctly know the surface temperature of the LED grain 2. The adhesive gel 30 may be made of polymer and metal compound. Preferably, the adhesive gel 30 is made of metal compound to have better heat conduction efficiency than that of the polymer. Preferably, the adhesive gel 30 has a thickness of about 10 nm such that the temperature gradient between the top face and bottom face of the adhesive gel 30 is small and the temperature sensor 3 is able to detect the temperature of the LED grain 2 correctly.

As shown in the accompanying drawings of FIG. 1 and FIG. 2, multiple electrodes are formed on the top of the insulation layer 13 and include driving electrodes 70, temperature sensing electrodes 71 and luminosity sensing electrodes 72. The driving electrodes 70 are respectively and electrically connected to corresponding LED grains 2 via a metal wire 700 which is formed by wire bonding as well as corresponding electrodes (positive and negative electrodes of a direct current power source). A contact pad 701 is formed on the metal wire 700 for connection to foreign devices. The two temperature sensing electrodes 71 are, via wire bonding, electrically connected to the temperature sensor 3 from corresponding electrodes (positive and negative electrodes of a direct current power source) through a metal wire 710. The metal wire 710 is electrically connected to contact pads (not shown) for connection to foreign devices. One of the luminosity sensing electrodes 72 extends through the insulation layer 13 via a metal wire 720 and reaches the silicone substrate 1. The other one of the luminosity sensing electrodes 72 extends through the insulation layer 13 via a metal wire 720 and reaches the luminous sensor 4. The two luminous sensors 4 respectively have a corresponding contact pad on the metal wire 720 to respectively direct the N type characteristic from the silicone substrate 1 and the P type characteristic from the luminous sensor 4 to the surface of the silicone substrate 1 for connection to a foreign device.

It is noted from the aforementioned description that the temperature sensor 3 as well as the luminous sensor 4 are formed in a single process while the silicone substrate 1 is ready. Then the LED grains 2 are encapsulated by encapsulation gel 5 to complete the manufacture process of the LED module. After the LED module is completed, it is noted that the LED module not only has ability to detect temperature in real time, it also has the ability to detect luminosity of the LED grains 2.

In addition to the advantages, the LED module also has the heat insulation layer 12 as well as the heat conducting plate 6 and the heat conducting gel 11 installed or embedded in the silicone substrate 1 to fast dissipate or isolate heat from influence to the LED grains 2. Therefore, it is expected that the LED module of the present invention has much longer life span, compared with the conventional structure, and lower power consumption. Further, without the adding of foreign or additional luminous or temperature detecting elements to detect luminosity and temperature in real time, the LED module of the present invention is much simple and inexpensive.

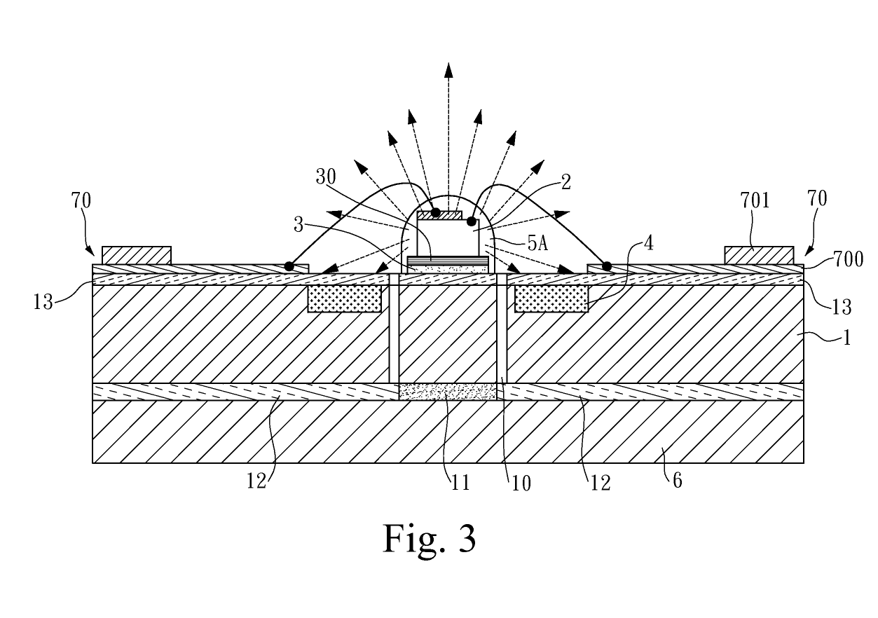

With reference to FIG. 3 of the other embodiment of the present invention, the LED module constructed in accordance with the embodiment of the present invention has a silicone substrate 1 and a LED grain 2. The silicone substrate 1 still has a temperature sensor 3 and a luminous sensor 4 both manufactured in the silicone substrate 1 in a single manufacture process. The difference is that the encapsulation gel 5A encloses only the LED grain 2 to avoid the LED grain 2 from direct contact with air.

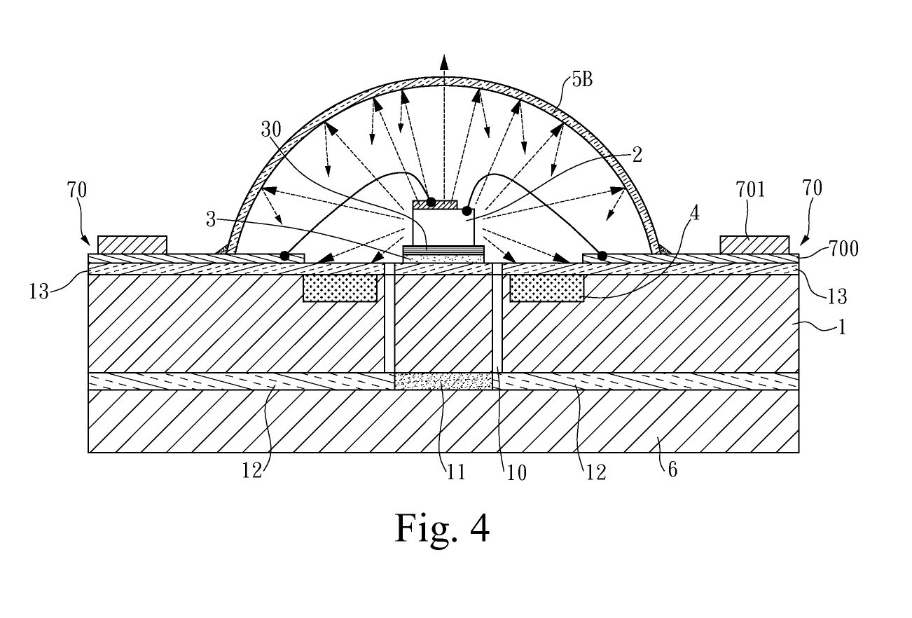

With reference to FIG. 4, the third embodiment of the present invention, the LED module in this embodiment also has a silicone substrate 1 and a LED grain 2. The silicone substrate 1 still has a temperature sensor 3 and a luminous sensor 4 both manufactured in the silicone substrate 1 in a single manufacture process. The difference is that the encapsulation gel 5B enclosing the LED grain 2 the same as that of encapsulation gel 5A in FIG. 3 has multiple escape holes 50B to dissipate heat generated from the LED grain 2. Also, the internal surface of the encapsulation gel 5B in this embodiment increases reflection from the LED grain 2.

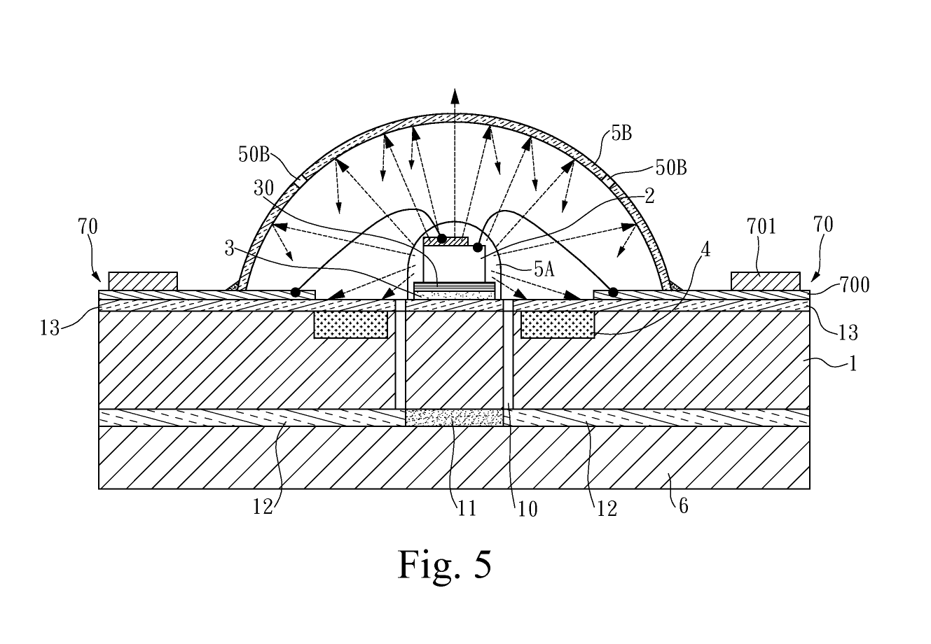

Still another embodiment is shown in FIG. 5. Under the construction of the embodiment shown in FIG. 4, another encapsulation gel 5A is applied to the LED grain 2 to prevent the LED grain 2 from direct contact with air and the escape holes 50B defined in the encapsulation gel 5B helps reflection from the LED grain 2.

While the invention has been described in connection with what is considered the most practical and preferred embodiment, it is understood that this invention is not limited to the disclosed embodiment but is intended to cover various arrangements included within the spirit and scope of the broadest interpretation so as to encompass all such modifications and equivalent arrangements.

What is claimed is:

1. An LED module comprising:
a silicone substrate;
an LED grain mounted on a face of the silicone substrate;
a temperature sensor formed under the LED grain;
a luminous sensor formed close to the LED grain; and
an encapsulation gel enclosing the LED grain, wherein the LED grain, the luminous sensor and the temperature sensor are electrically connected to electrodes for connection to foreign devices.

2. The LED module as claimed in claim 1, wherein the silicone substrate is a N-type substrate and the luminous sensor is a P-type doped area annularly formed around the LED grain with the temperature sensor sandwiched between the LED grain and the silicone substrate.

3. The LED module as claimed in claim 2, wherein the temperature sensor is a resistive metal membrane and formed by deposition and lithography in the silicone substrate, the temperature sensor is combined with the LED grain due to application of adhesive gel at bottom of the LED grain, the adhesive gel is selected from the group consisting of polymer and metal compound.

4. The LED module as claimed in claim 3, wherein a trough is annularly defined around the LED grain to prevent heat conduction, the P-type doped area is located outside the trough.

5. The LED module as claimed in claim 4, wherein a heat conducting plate is provided at bottom of the silicone substrate and made of a material selected from the group consisting of silicone, metal and ceramic, a heat conducting gel is sandwiched between the heat conducting plate and the trough and a heat insulation layer is sandwiched between a bottom defining the trough and the heat conducting plate.

6. The LED module as claimed in claim 5, wherein an insulation layer is applied on top of the silicone substrate and within as well as outside the trough, the temperature sensor is located within the trough and on top of the insulation layer.

7. The LED module as claimed in claim 6, wherein the electrodes are formed outside the trough and on top of the insulation layer to electrically connect to foreign device via a contact pad formed on a metal wire which is deposited on top of the insulation layer.

8. The LED module as claimed in claim 7, wherein the electrodes includes two LED driving electrodes, two temperature sensing electrodes, and two luminosity sensing electrodes, the two LED driving electrodes are electrically connected to the LED grain, the two temperature sensing electrodes are respectively and electrically connected to the temperature sensor, one of the luminosity sensing electrodes is electrically connected to the silicone substrate and the other one of the luminosity sensing electrodes is electrically connected to P-type doped area.

9. The LED module as claimed in claim 8, wherein the two LED driving electrodes are electrically connected to the LED grain via a metal wire, the two temperature sensing electrodes are respectively and electrically connected to the temperature sensor via a metal wire, one of the luminosity sensing electrodes is electrically connected to the silicone substrate via a metal wire and the other one of the luminosity sensing electrodes is electrically connected to P-type doped area via a metal wire.

10. The LED module as claimed in claim 1, wherein the encapsulation gel is solid to enclose the LED grain, the temperature sensor and the luminous sensor.

11. The LED module as claimed in claim 1, wherein the encapsulation gel is solid to enclose only the LED grain.

12. The LED module as claimed in claim 1, wherein the encapsulation gel is hollow to enclose the LED grain, the temperature sensor and the luminous sensor.

13. The LED module as claimed in claim 1, wherein the encapsulation gel is hollow to enclose the LED grain, the temperature sensor and the luminous sensor so as to allow heat to escape from escape holes defined in a side face defining the encapsulation gel.

14. The LED module as claimed in claim 13, wherein the encapsulation gel includes a first hollow encapsulation gel to enclose the LED grain, the temperature sensor and the luminous sensor so as to allow heat to escape from escape holes defined in a side face defining the encapsulation gel and a solid second encapsulation gel enclosing the LED grain to prevent the LED grain from direct contact with air.
